(19) United States
(12) Patent Application Publication
(10) Pub. No.: US 2026/0025112 A1
(43) Pub. Date: Jan. 22, 2026

(54) Radio frequency amplifier module, radio frequency antenna module, and antenna array for beamforming

(71) Applicant: Amtery Corporation, Taipei City (TW)

(72) Inventors: Shu-Hsien Chou, Taipei City (TW); Nai-Wen Chang, Taipei City (TW); Chun-Hsien Lin, Taipei City (TW)

(73) Assignee: Amtery Corporation, Taipei City (TW)

(21) Appl. No.: 18/823,710

(22) Filed: Sep. 4, 2024

(30) Foreign Application Priority Data
Jul. 22, 2024 (TW) 113127294

(51) Int. Cl. H03F 3/19; H01Q 3/36

(52) U.S. Cl. CPC H03F 3/19; H01Q 3/36; H03F 2200/451

(57) ABSTRACT

A radio frequency amplifier module includes a phase shifter, a radio frequency amplifier, a memory and a microcontroller. The phase shifter is used to shift a phase of an input radio frequency signal by a phase offset to generate a phase shifted radio frequency signal. The radio frequency amplifier is coupled to the phase shifter, and used to amplify the phase shifted radio frequency signal to output an amplified radio frequency signal. The memory is used to store a lookup table. The microcontroller is coupled to the phase shifter and the memory, and used to read the lookup table according to at least a frequency of the input radio frequency signal to output the phase offset to the phase shifter.

### BACKGROUND OF THE INVENTION

### 1. Field of the Invention

The present invention is related to a radio frequency amplifier module and a radio frequency antenna module, in particular to a replaceable radio frequency amplifier module and a replaceable radio frequency antenna module for an antenna array.

### 2. Description of the Prior Art

Phased antenna array is a technology that uses multiple antenna units to control the radiation direction by adjusting the relative phase of each unit. This technology is called “beamforming”. Phased antenna array can have a few to thousands of transmitters. They play a role in various applications, including Wi-Fi, radars and 5G.

Specifically, phased antenna array achieve beamforming by adjusting the phase difference between the drive signals sent to each transmitter in the array. This allows control over the radiation direction, pointing towards a specific target without physically moving the antenna array. For example, the Wi-Fi dipole antenna is an omnidirectional transmitter that uses beamforming to synthesize electromagnetic waves from multiple dipole antennas to control the directivity and gain of the signal.

In the 5G field, the key to phased antenna array is achieving wider bandwidth, further coverage and greater capacity in the millimeter wave band. This technology holds promise for wireless networks and is advancing.

When the signals emitted by each transmitter in a phased array are precise in phase, they interfere constructively, resulting in strong radiation, but only in specific directions. The radiation direction is controlled by adjusting the phase difference among signals sent to different transmitters. To achieve this phase difference, a small time delay needs to be introduced among the signals sent to a series of consecutive transmitters in the phased array. Outside the main beam direction, the intensity of the beam decreases. Since the signal is periodic, there will also be side lobes in the beam pattern. However, beamforming can indeed obtain a very strong beam along a specific direction.

FIG. 1A is a schematic diagram of a monopole antenna 102 in the prior art, and FIG. 1B is a schematic diagram of a monopole antenna array 104 in the prior art. The monopole antenna 102 is a basic antenna commonly used in wireless communications and broadcasting. The monopole antenna 102 transmits signals uniformly in all directions in a plane perpendicular to the antenna axis. The radiation pattern of the monopole antenna 102 resembles a donut-shaped and lacks directivity. The radiation intensity is 0 in the direction aligned with the antenna axis, and electromagnetic waves are emitted equally on a plane perpendicular to the antenna axis.

A phased antenna array can includes multiple monopole antennas 102 (referred to as a monopole antenna array 104) controlling the radiation direction by adjusting the phase of each monopole antenna 102. When multiple monopole antennas 102 form a phased array, their wave surfaces interfere with each other to form a flat phase wave surface. By adjusting the phase difference, the phased array can achieve beamforming, radiating in a specific direction. As shown in FIG. 1B, when the radiation direction of the monopole antenna array 104 needs to be adjusted to θ, the phase difference between two adjacent monopole antennas 102 must be given by ΔΦ=(2π/λ)L sin θ. To achieve the desired phase difference, the individual phases of the first to sixth monopole antennas 102 are adjusted to 0, ΔΦ, 2ΔΦ, 3ΔΦ, 4ΔΦ, 5ΔΦ. This constructive interference result in the strongest beam in the θ direction. The monopole array antenna 104 is widely used in wireless communications, radars, 5G and other fields to offer high directivity and gain. In summary, the phased antenna array achieves beamforming by controlling the phase difference between the monopole antennas 102, making it an important technology in modern communication systems.

Beamforming of phased antenna array is crucial for high-frequency electromagnetic waves to overcome losses during transmission. A properly sized phased antenna array allows directing the radiation from a high-gain transmitter at a specific angle. Phased array technology enhances the collective signals or the characteristics of the radiation pattern. After forming the antenna array, various parameters and quantities have been improved, the parameters and quantities including:
1. Power intensity: the power intensity increases due to summing the powers of the individual signals.
2. Beamforming: the phase differences of single signals control the shape of the beam, resulting in a narrower radiation beam compared to a single antenna.
3. Beam steering: flexible beam steering without mechanical steering, achieved through the electronic phase shifters.
4. Multiple beams: phased antennas array synthesizes multiple beams in different directions using phase shifters.
5. Optional digital/mixer solution: phase offsets can be achieved via analog or digital ways. Analog phase shifters rely on signal downconversion and time shifting, while digital phase shifters shift an intermediate frequency (IF) or a local oscillator (LO) signal.
6. Weight: the phased antenna array is lighter in weight than a single antenna using the mechanical steering device.
7. Cost: the phased antenna array is less expensive than a mechanically steered antenna, while maintaining the same angular resolution.
8. Reliability: the phased antenna array is much more reliable than a single antenna. If one antenna is damaged, the remaining antennas in the array continues to operate with a slightly altered radiation pattern.

These characteristics make phased antenna array an important technology in modern communication systems.

However, when using a phased antenna array, depending on the frequency of the radio frequency signal and the temperature of the environment, the antenna unit and the radio frequency amplifier unit of the phased array antenna may produce phase offset errors. The phase offset errors may lead to misalignment of the phase differences of the phased antenna array and the inability to transmit electromagnetic wave beams in the ideal direction.

### SUMMARY OF THE INVENTION

An embodiment of the present invention provides a radio frequency amplifier module. The radio frequency amplifier module includes a phase shifter, a radio frequency amplifier, a memory and a microcontroller. The phase shifter is used to shift a phase of an input radio frequency signal by a phase offset to generate a phase shifted radio frequency signal. The radio frequency amplifier is coupled to the phase shifter, and used to amplify the phase shifted radio frequency signal to output an amplified radio frequency signal. The memory is used to store a lookup table. The microcontroller is coupled to the phase shifter and the memory, and used to read the lookup table according to at least a frequency of the input radio frequency signal to output the phase offset to the phase shifter.

Another embodiment of the present invention provides a radio frequency antenna module. The radio frequency antenna module includes a radio frequency antenna, a memory and a microcontroller. The radio frequency antenna is used to transmit an amplified radio frequency signal. The memory is used to store a lookup table. The microcontroller is coupled to the memory, and used to read a lookup table according to at least a frequency of the amplified radio frequency signal to output a phase offset for a radio frequency signal to be shifted.

Another embodiment of the present invention provides an antenna array. The antenna array includes a radio frequency signal generator, a phase shifter, a radio frequency amplifier module and a radio frequency antenna module. The radio frequency signal generator is used to generate a radio frequency signal. The phase shifter is coupled to the radio frequency signal generator, and used to calibrate the radio frequency signal to generate an input radio frequency signal. The radio frequency amplifier module is coupled to the phase shifter, and includes a radio frequency amplifier and a memory. The radio frequency amplifier is used to amplify the input radio frequency signal to generate an amplified radio frequency signal. The memory is used to store a lookup table that stores phase offsets of the radio frequency amplifier corresponding to a plurality of radio frequencies. The radio frequency antenna module is coupled to the radio frequency amplifier module and includes a radio frequency antenna. The radio frequency antenna is used to transmit the amplified radio frequency signal.

Another embodiment of the present invention provides an antenna array. The antenna array includes a radio frequency signal generator, a first phase shifter, a radio frequency amplifier module, a radio frequency antenna module, and a third microcontroller. The radio frequency signal generator is used to generate a radio frequency signal. The first phase shifter is coupled to the radio frequency signal generator, and used to calibrate the radio frequency signal to generate an input radio frequency signal. The radio frequency amplifier module includes a second phase shifter, a radio frequency amplifier, a first memory and a first microcontroller. The second phase shifter is coupled to the first phase shifter, and used to shift a phase of the input radio frequency signal to generate a phase shifted radio frequency signal. The radio frequency amplifier is coupled to the second phase shifter, and used to amplify the phase shifted radio frequency signal to output an amplified radio frequency signal. The first memory is used to store a first lookup table that stores phase offsets of the radio frequency amplifier corresponding to a plurality of radio frequencies. The first microcontroller is coupled to the second phase shifter and the first memory, and used to read the first lookup table according to at least a frequency of the input radio frequency signal to output a phase offset for the input radio frequency signal to be shifted to the second phase shifter. The radio frequency antenna module includes a radio frequency antenna, a second memory and a second microcontroller. The radio frequency antenna is coupled to the radio frequency amplifier, and used to transmit the amplified radio frequency signal. The second memory is used to store a second lookup table that stores phase offsets of the radio frequency antenna corresponding to a plurality of radio frequencies. The second microcontroller is coupled to the second memory, and used to read the second lookup table according to at least the frequency of the amplified radio frequency signal to output a phase offset of the radio frequency antenna. The third microcontroller is coupled to the second microcontroller and the first phase shifter, and used to output to the first phase shifter a phase offset for the radio frequency signal to be shifted according to at least the phase offset of the radio frequency antenna.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram of a monopole antenna in the prior art.

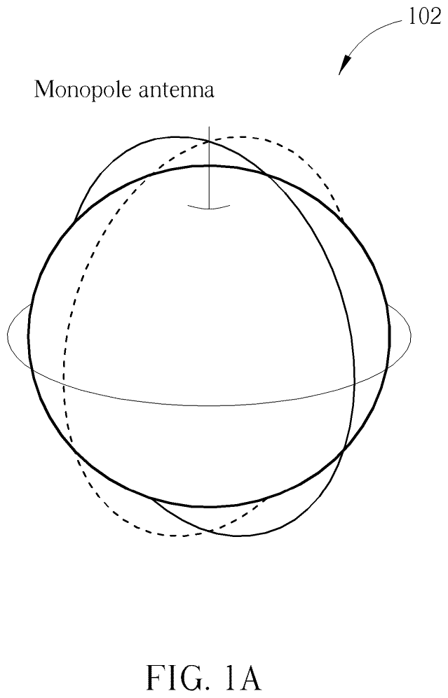

FIG. 1B is a schematic diagram of a monopole antenna array in the prior art.

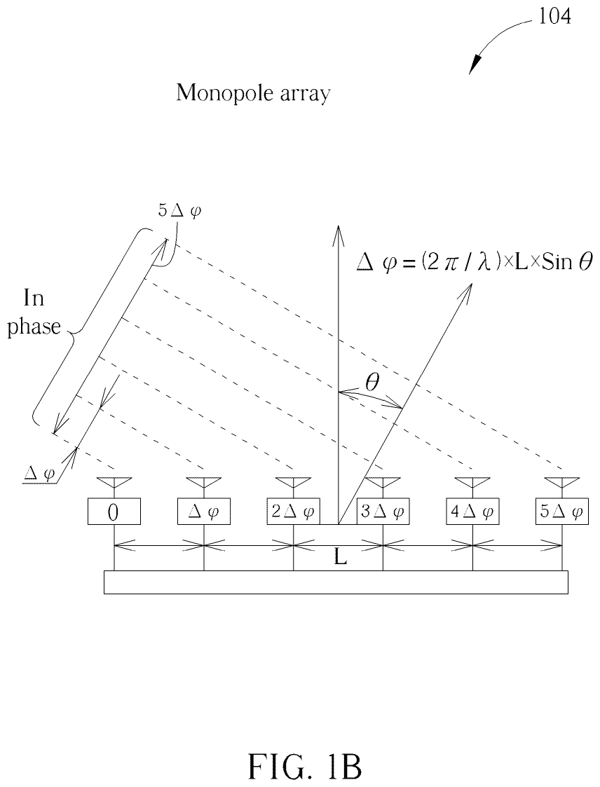

FIG. 2 is a block diagram of a radio frequency amplifier module in an embodiment of the present invention.

FIG. 3 is a block diagram of a radio frequency amplifier module in another embodiment of the present invention.

FIG. 4 is a block diagram of a radio frequency antenna module in an embodiment of the present invention.

FIG. 5 is a block diagram of a radio frequency antenna module in another embodiment of the present invention.

FIG. 6A is a block diagram of a phased antenna array in an embodiment of the present invention.

FIG. 6B is a block diagram of a phased antenna array in another embodiment of the present invention.

FIG. 7 is a block diagram of a phased antenna array in another embodiment of the present invention.

FIG. 8 is a block diagram of a phased antenna array in another embodiment of the present invention.

### DETAILED DESCRIPTION

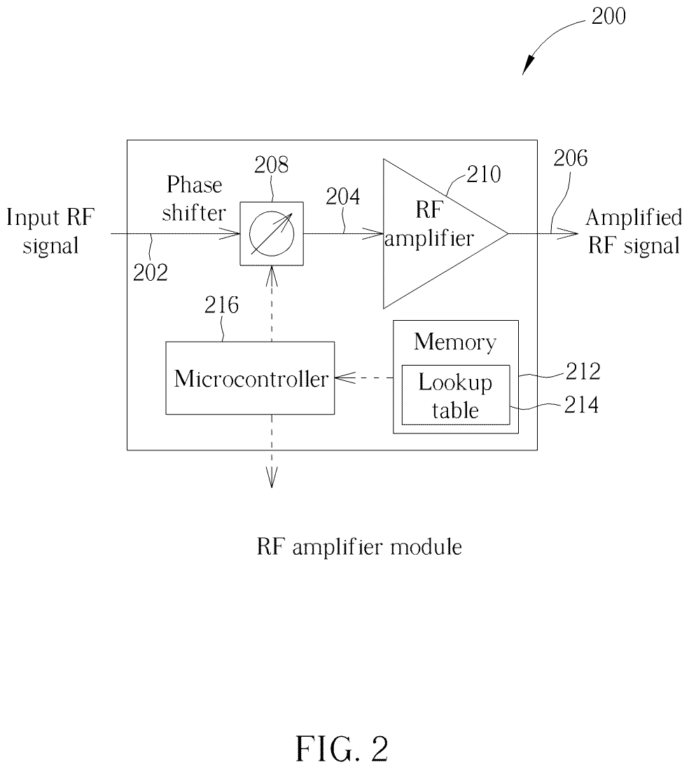

FIG. 2 is a block diagram of a radio frequency amplifier module 200 in an embodiment of the present invention. The radio frequency (RF) amplifier module 200 for a phased antenna array can be coupled before an antenna module and after a signal generator and a phase shifter to amplify the radio frequency signal. In other embodiments, the radio frequency amplifier module 200 can also be used in other circuits, but is not limited thereto. The RF amplifier module 200 includes a phase shifter 208, an RF amplifier 210, a memory 212 and a microcontroller 216. First, the input RF signal 202 is fed into the phase shifter 208 of the RF amplifier module 200. After appropriate phase calibration, a phase-shifted RF signal 204 is generated and then fed into the RF amplifier 210. The RF amplifier 210 amplifies the phase-shifted RF signal 204 to output an amplified RF signal 206. The memory 212 of the radio frequency amplifier module 200 stores a lookup table 214. The lookup table 214 contains phase offsets of the radio frequency amplifier 210 corresponding to a plurality of radio frequencies. The microcontroller 216 can determine the phase offsets of the current radio frequency signal by querying the lookup table 214. The phase offset of the radio frequency amplifier 210 corresponding to the RF frequency is then calibrated via the phase shifter 208. When a plurality of RF amplifier modules 200 are used in a phased antenna array, the phase of the amplified RF signal 206 from each RF amplifier module 200 is calibrated, ensuring that beamforming is not affected by the phase offsets. The benefit of self-calibrating the phase offset using multiple RF amplifier modules 200 lies in that the ability to directly replace a damaged RF amplifier module 200 without recalibrating the entire phased antenna array, thus saving time and efforts.

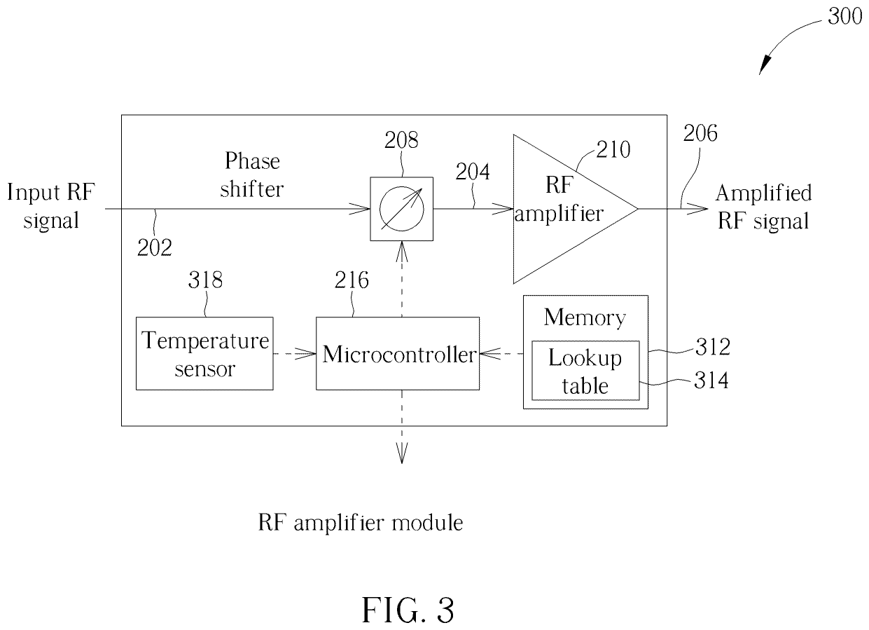

FIG. 3 is a block diagram of a radio frequency amplifier module 300 in another embodiment of the present invention. Compared with the RF amplifier module 200, the RF amplifier module 300 further includes a temperature sensor 318 coupled to the microcontroller 216 for sensing the temperature of the RF amplifier module 300. The lookup table 314 in the memory 312 stores phase offsets of the RF amplifier 210 corresponding to a plurality of temperatures and a plurality of RF frequencies. The lookup table 314 can be established by measuring the RF amplifier module 300 in a temperature-controlled box using a vector network analyzer (VNA), thereby obtaining a plurality of phase offsets of the RF amplifier 210 at various frequencies and temperatures. The microcontroller 216 can query the lookup table 314 according to the temperature of the RF amplifier module 300 measured by the temperature sensor 318 and the RF frequency of the input RF signal, so as to determine the phase offset of the RF amplifier 210. The phase shifter 208 calibrates the phase offset to ensure that the phase of the amplified RF signal 206 from the RF amplifier module 300 remains unaffected by temperature and RF frequency. When multiple RF amplifier modules 300 are used in a phased antenna array, the phase of the amplified RF signal 206 from each RF amplifier module 300 is calibrated to maintain accurate beamforming regardless of the phase offsets. The benefit of self-calibrating the phase offset through multiple RF amplifier modules 300 lies in that the ability to directly replace a damaged RF amplifier module 200 without recalibrating the entire phased antenna array, thus saving time and efforts.

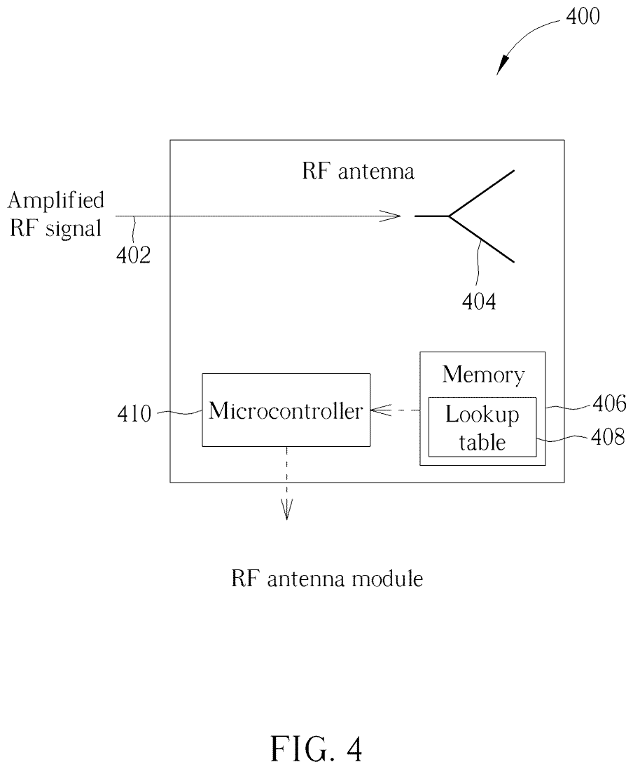

FIG. 4 is a block diagram of a radio frequency antenna module 400 in an embodiment of the present invention. The radio frequency antenna module 400 used for the antenna array can be coupled behind the RF amplifier modules 200 or 300 to transmit the amplified RF signal 402. In other embodiments, the radio frequency antenna module 400 can also be used in other circuits, but is not limited thereto. The radio frequency antenna module 400 includes a radio frequency antenna 404, a memory 406 and a microcontroller 410. First, the amplified radio frequency signals 402 from the radio frequency amplifier modules 200 and 300 are fed into the radio frequency antenna 404 of the radio frequency antenna module 400, as allowing the radio frequency antenna 404 to radiate the amplified radio frequency signal 402 into the surrounding space. The memory 406 of the radio frequency antenna module 400 contains a lookup table 408. The lookup table 408 stores the phase offsets of the radio frequency antenna 404 corresponding to a plurality of RF frequencies. The microcontroller 410 can find the phase offsets of the current radio frequency by querying the lookup table 408. The phase offset of the radio frequency signal is calibrated via an external phase shifter. Therefore, the phase offsets of the RF antenna may not affect beamforming. In one embodiment, the radio frequency antenna 404 of the radio frequency antenna module 400 may be an omnidirectional antenna. In another embodiment, the RF antenna 404 of the RF antenna module 400 may be a directional antenna.

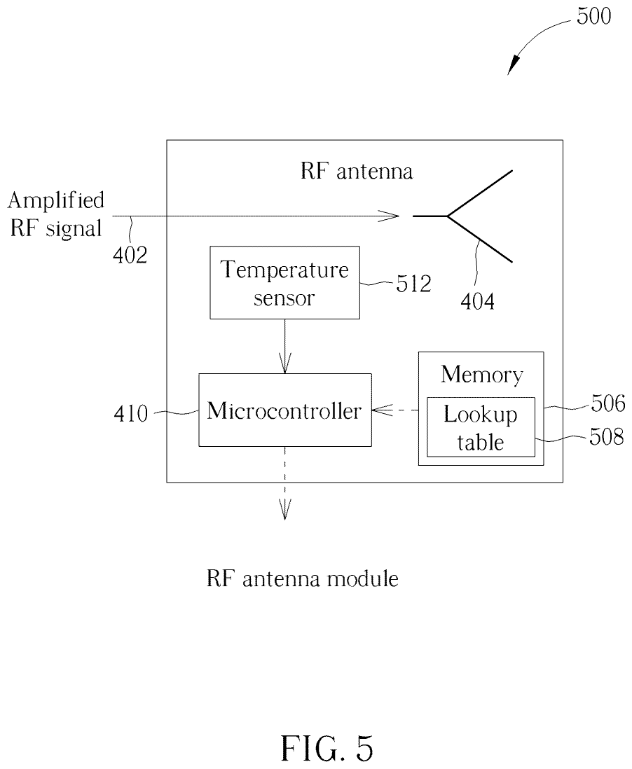

FIG. 5 is a block diagram of a radio frequency antenna module 500 in another embodiment of the present invention. Compared to the radio frequency antenna module 400, the radio frequency antenna module 500 further includes a temperature sensor 512 coupled to the microcontroller 410 for sensing the temperature of the radio frequency antenna module 500. The lookup table 508 in the memory 506 of the RF antenna module 500 stores phase offsets of the RF antenna 404 corresponding to a plurality of temperatures and a plurality of RF frequencies. The lookup table 508 can be established by measuring the RF antenna module 500 and the standard horn antenna using a vector network analyzer (VNA) in a temperature-controlled box in a non-reflection chamber, thereby obtaining the plurality of phase offsets of the RF antenna 404 for various frequencies and various temperatures. The microcontroller 410 can find the phase offset of the radio frequency antenna 404 by querying the lookup table 508 according to the RF frequency and the temperature of the radio frequency antenna module 500 measured by the temperature sensor 512. Then, the phase offset can be calibrated using the external phase shifter, ensuring that the phase of the amplified radio frequency signal 402 radiated by the radio frequency antenna module 500 remains unaffected by temperature and/or frequency variation. When multiple radio frequency antenna modules 500 are used in a phased antenna array, the phase offset of the amplified radio frequency signal 402 transmitted by each radio frequency antenna module 500 is calibrated. As a result, the radiation angle of beamforming remains unaffected. In one embodiment, the radio frequency antenna 404 of the radio frequency antenna module 500 may be an omnidirectional antenna. In another embodiment, the radio frequency antenna 404 of the radio frequency antenna module 500 may be a directional antenna.

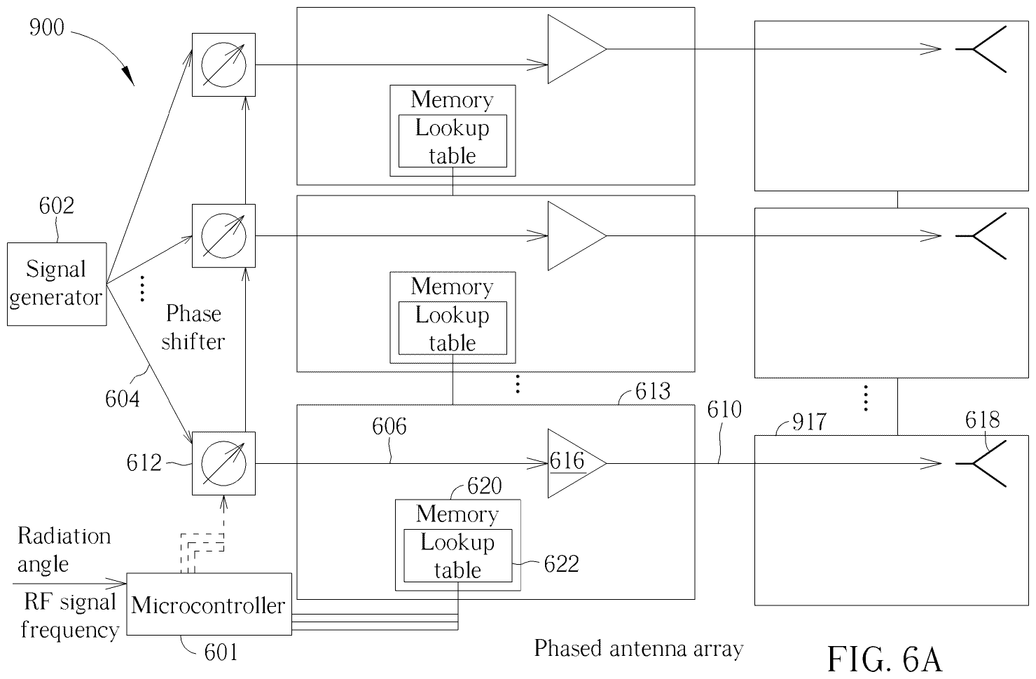

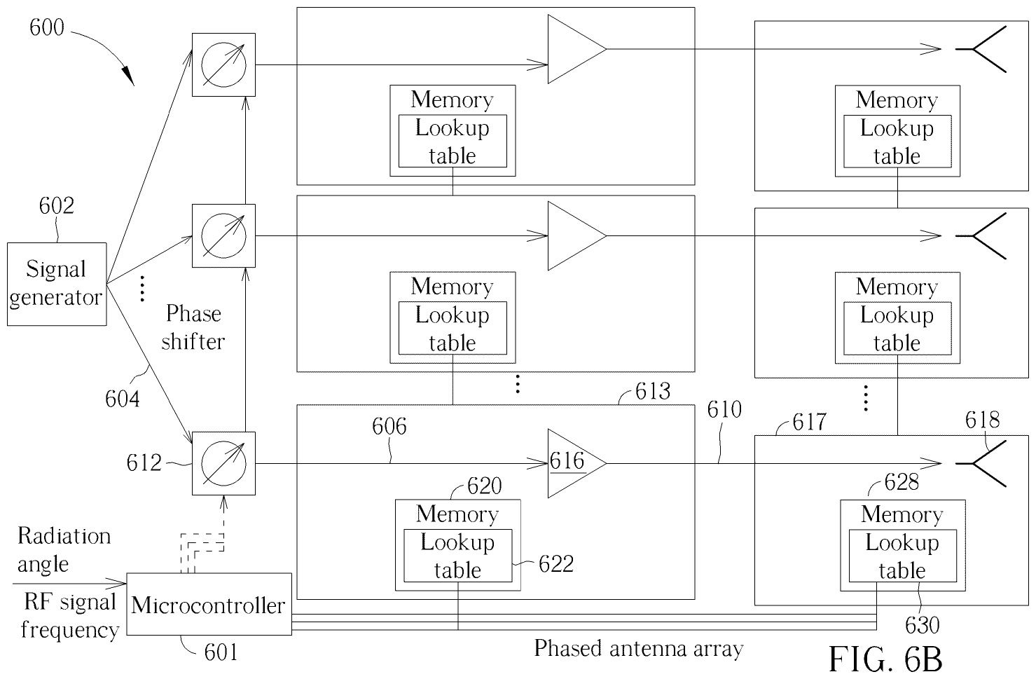

FIG. 6A is a block diagram of a phased antenna array 900 in an embodiment of the present invention. The phased antenna array 900 includes a signal generator 602, a microcontroller 601, a plurality of phase shifters 612, a plurality of radio frequency amplifier modules 613 and a plurality of radio frequency antenna modules 917. The signal generator 602 generates a radio frequency signal 604. The radio frequency signal 604 is fed into a plurality of phase shifters 612. After appropriate phase shifting, a plurality of input radio frequency signals 606 are generated and fed into the plurality of radio frequency amplifier modules 613, and then a plurality of amplified radio frequency signals 610 are generated and then fed into a plurality of radio frequency antenna modules 917. The multiple radio frequency antenna modules 917 will radiate the amplified radio frequency signals 610 into the surrounding space and produce constructive interference at the desired radiation angle, thus achieving beamforming.

In the embodiment of FIG. 6A, each RF amplifier module 613 includes a memory 620 and an RF amplifier 616. The memory 620 contains a lookup table 622 that stores phase offsets corresponding to the RF amplifier 616 at various frequencies. The microcontroller 601 queries a plurality of lookup tables 622 in the plurality of radio frequency amplifier modules 613 according to the frequency of the radio frequency signal 604, and determines the phase offsets caused by the plurality of radio frequency amplifiers 616 of the phased antenna array 900, enabling the plurality of phase shifters 612 to perform phase calibration on the radio frequency signal 604 affected by the phase offset of the RF amplifier 616. The radio frequency antenna module 917 includes a radio frequency antenna 618. The microcontroller 601 determines the phase offsets of the plurality of radio frequency antennas 618 of the plurality of radio frequency antenna modules 917 according to the radiation angle of the phased antenna array 900, enabling the phase shifters 612 to perform phase shifting on the radio frequency signals 604. In this embodiment, the phase shifter 612 can perform phase shifting according to the different radiation angles of the plurality of amplified radio frequency signals 610 and the phase offsets caused by the plurality of radio frequency amplifiers 616 to achieve beamforming.

FIG. 6B is a block diagram of a phased antenna array 600 in another embodiment of the present invention. The phased antenna array 600 includes a signal generator 602, a microcontroller 601, a plurality of phase shifters 612, a plurality of radio frequency amplifier modules 613 and a plurality of radio frequency antenna modules 617. The signal generator 602 generates a radio frequency signal 604. The radio frequency signal 604 is fed into a plurality of phase shifters 612. After appropriate phase shifting, a plurality of input radio frequency signals 606 are generated and fed into a plurality of radio frequency amplifier modules 613, and then a plurality of amplified radio frequency signals 610 are generated and then fed into a plurality of radio frequency antenna modules 617. The plurality of radio frequency antenna modules 617 will radiate the amplified radio frequency signals 610 into space and produce constructive interference at the desired radiation angle, thus achieving beamforming.

In the embodiment of FIG. 6B, each RF amplifier module 613 includes a memory 620 and a RF amplifier 616. The memory 620 contains a lookup table 622 that stores phase offsets corresponding to the RF amplifier 616 at various frequencies. The microcontroller 601 queries a plurality of lookup tables 622 in the plurality of radio frequency amplifier modules 613 according to the frequency of the radio frequency signal 604, and determines the phase offsets caused by the plurality of radio frequency amplifiers 616 of the phased antenna array 600. Then, the plurality of phase shifters 612 calibrate phase offsets of the radio frequency signals 604 caused by the plurality of radio frequency amplifiers 616. Each radio frequency antenna module 617 includes a memory 628 and a radio frequency antenna 618. The memory 628 has a lookup table 630 that stores phase offsets of the radio frequency antenna 618 corresponding to various RF frequencies. The microcontroller 601 queries a plurality of lookup tables 630 in the plurality of radio frequency antenna modules 617 according to the frequency of the radio frequency signal 604 and the radiation angle of the phased antenna array 600, and determines the phase offsets of the plurality of radio frequency antennas 618 of the phased antenna array 600. Therefore, the phase shifters 612 perform phase calibration on the radio frequency signal 604 to compensate for the phase offsets caused by the radio frequency antenna 618 and the radiation angles of beamforming. In this embodiment, the phase offsets caused by the RF amplifier module 613 and the RF antenna module 617 are calibrated together using the phase shifter 612, and the phase shifter 612 can also perform phase shifting according to different radiation angles of beamforming simultaneously.

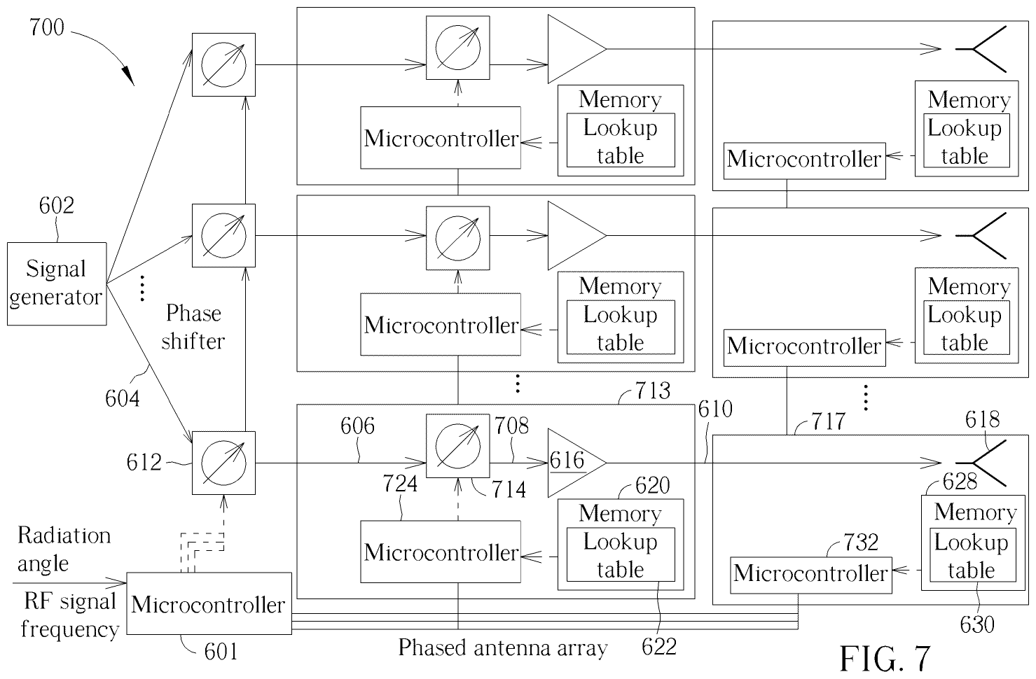

FIG. 7 is a block diagram of a phased antenna array 700 in another embodiment of the present invention. Compared with the radio frequency amplifier module 613 of the phased antenna array 600, the RF amplifier module 713 of the phased antenna array 700 further includes a phase shifter 714 and a microcontroller 724. Compared with the radio frequency antenna module 617 of the phased antenna array 600, the radio frequency antenna module 717 of the phased antenna array 700 further includes a microcontroller 732. The signal generator 602 generates a radio frequency signal 604. The radio frequency signal 604 is fed into the phase shifter 612. After an appropriate phase shifting, an input radio frequency signal 606 is generated and fed into the phase shifter 714 of the radio frequency amplifier module 713. After passing through the phase shifter 714 of the radio frequency amplifier module 713, a phase shifted radio frequency signal 708 is generated and fed into the radio frequency amplifier 616. The RF amplifier 616 amplifies the phase shifted RF signal 708 to generate an amplified RF signal 610 and inputs the amplified RF signal 610 into the RF antenna module 717. Then, the RF antenna 618 of the RF antenna module 717 radiates the amplified RF signal 610 into space to form a beam.

The microcontroller 724 of the radio frequency amplifier module 713 reads the lookup table 622 and performs phase calibration on the input radio frequency signal 606 according to the frequency of the radio frequency signal 604 transmitted from the microcontroller 601 to calibrate the phase offset caused by the radio frequency amplifier module 713. The lookup table 622 stores the phase offsets of the radio frequency amplifier 616 corresponding to a plurality of radio frequencies. The benefit of self-calibrating the phase offset using the radio frequency amplifier module 713 lies in that the ability to directly replace a damaged radio frequency amplifier module 713 without recalibrating the phased antenna array 700 if the radio frequency amplifier 616 is damaged, thus saving time and efforts. In this embodiment, the microcontroller 732 of the radio frequency antenna module 717 outputs the phase to be calibrated of the amplified radio frequency signal 610 according to the frequency of the radio frequency 604 transmitted the signal from microcontroller 601 and the phase offsets of the lookup table 630, compensating for the phase offset caused by the RF antenna module 717.

The microcontroller 601 then calculates the phases that all radio frequency antenna modules 717 need to be shifted based on the radiation angle of the phased array antenna 700, and then controls the phase shifter 612 to perform phase shifting on the radio frequency signal 604. This phase shifting includes calibrating the phase offset caused by the radio frequency antenna 618 and the phase offset required for beam forming. The lookup table 630 in the memory 628 stores phase offsets of the radio frequency antenna 618 corresponding to a plurality of radio frequencies.

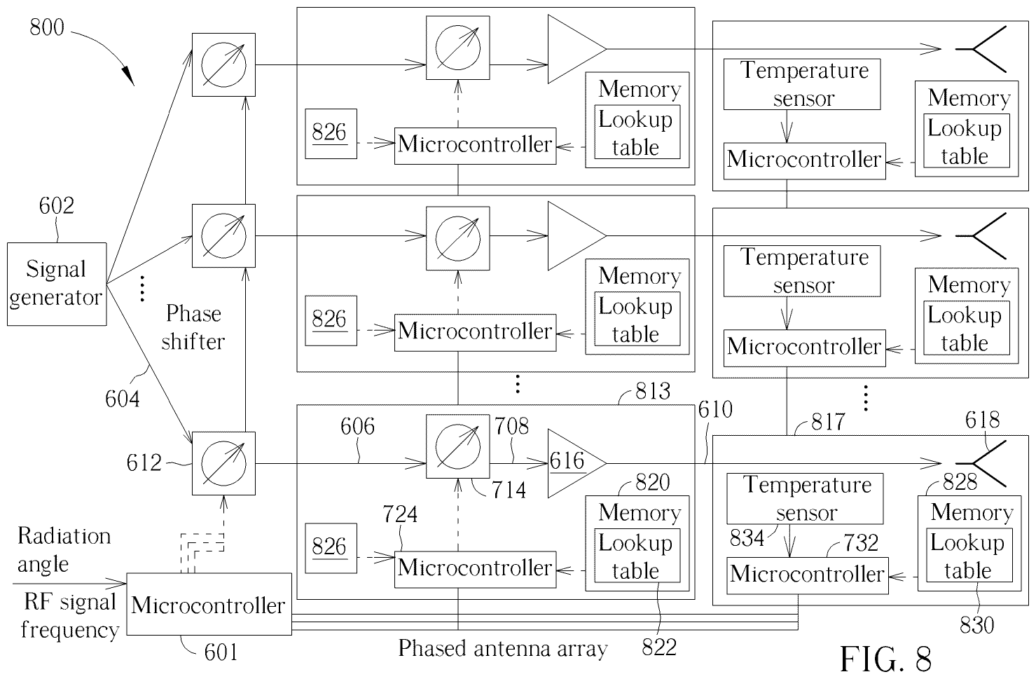

FIG. 8 is a block diagram of a phased antenna array 800 in another embodiment of the present invention. Compared with the RF amplifier module 713 of the phased antenna array 700, the RF amplifier module 813 of the phased antenna array 800 further includes a temperature sensor 826. Compared with the radio frequency antenna module 717 of the phased antenna array 700, the radio frequency antenna module 817 of the phased antenna array 800 further includes a temperature sensor 834. The signal generator 602 generates a radio frequency signal 604. The radio frequency signal 604 is fed into the phase shifter 612. After an appropriate phase shifting, an input radio frequency signal 606 is generated and fed into the phase shifter 714 of the radio frequency amplifier module 813. After passing through the phase shifter 714 of the radio frequency amplifier module 813, a phase shifted radio frequency signal 708 is generated and fed into the radio frequency amplifier 616. The RF amplifier 616 amplifies the phase shifted RF signal 708 to generate an amplified RF signal 610 and input it into the RF antenna module 817. Then, the RF antenna 618 of the RF antenna module 817 radiates the amplified RF signal 610 into space to form a beam. The microcontroller 724 of the radio frequency amplifier module 813 controls the phase shifter 714 by reading the lookup table 822 according to the frequency of the RF signal 604 transmitted from the microcontroller 601 and the temperature read by the temperature sensor 826.

The input radio frequency signal 606 undergoes phase calibration to address the phase offset caused by the radio frequency amplifier module 813. The lookup table 822 in the memory 820 stores phase offsets of the RF amplifier 616 corresponding to a plurality of temperatures and a plurality of RF frequencies. The benefit of self-calibrating the phase offset using the radio frequency amplifier module 813 lies in the ability to directly replace the radio frequency amplifier module 813 without recalibrating the entire phased antenna array 800 if the radio frequency amplifier 616 is damaged, thus saving time and efforts. In this embodiment, the microcontroller 732 of the radio frequency antenna module 817 reads the frequency of the radio frequency signal 604 transmitted from the microcontroller 601, the temperature measured by the temperature sensor 834, and the phase offsets of the lookup table 830. The calibration data is transmitted by the microcontroller 732 to calibrate the phase offset caused by the radio frequency antenna module 817. The microcontroller 601 then calculates the phases that all radio frequency antenna modules 817 need to be shifted based on the radiation angle of the phased antenna array 800, and then controls the phase shifter 612 to perform phase shifting on the radio frequency signal 604. This phase shifting includes the phase offset caused by the radio frequency antenna 618 and the phase offset required for beamforming. The lookup table 830 in the memory 828 stores phase offsets of the radio frequency antenna 618 corresponding to a plurality of temperatures and a plurality of radio frequencies.

In summary, when using the phase shifter 612 to implement the phased antenna arrays 600, 700, 800, and 900, the RF signal 604 requires phase calibration to account for the phase offsets caused by the RF amplifier 616 and the RF antenna 618. In the embodiment of the present invention, if the radio frequency amplifier 616 of the radio frequency amplifier modules 613, 713, and 813 is damaged, the entire radio frequency amplifier module 613, 713, and 813 can be directly replaced. In addition, the radio frequency amplifier modules 713, and 813 are capable of self-phase calibration. The present invention enhance the flexibility and convenience of implementing the phased antenna arrays 600, 700, 800, and 900.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A radio frequency amplifier module comprising:
a phase shifter configured to shift a phase of an input radio frequency signal by a phase offset to generate a phase shifted radio frequency signal;
a radio frequency amplifier coupled to the phase shifter, and configured to amplify the phase shifted radio frequency signal to output an amplified radio frequency signal;
a memory configured to store a lookup table; and
a microcontroller coupled to the phase shifter and the memory, and configured to read the lookup table according to at least a frequency of the input radio frequency signal to output the phase offset to the phase shifter.

2. The radio frequency amplifier module of claim 1, wherein the lookup table stores phase offsets of the radio frequency amplifier corresponding to a plurality of radio frequencies.

3. The radio frequency amplifier module of claim 1, further comprising a temperature sensor coupled to the microcontroller, and configured to sense a temperature of the radio frequency amplifier module.

4. The radio frequency amplifier module of claim 3, wherein the lookup table stores phase offsets of the radio frequency amplifier corresponding to a plurality of temperatures and a plurality of radio frequencies.

5. The radio frequency amplifier module of claim 4, wherein the microcontroller reads the lookup table according to the frequency of the input radio frequency signal and the temperature of the radio frequency amplifier module to output the phase offset of the input radio frequency signal.

6. A radio frequency antenna module comprising:
a radio frequency antenna configured to transmit an amplified radio frequency signal;
a memory configured to store a lookup table; and
a microcontroller coupled to the memory, and configured to read a lookup table according to at least a frequency of the amplified radio frequency signal to output a phase offset for a radio frequency signal to be shifted.

7. The radio frequency antenna module of claim 6, wherein the lookup table stores phase offsets of the radio frequency antenna corresponding to a plurality of radio frequencies.

8. The radio frequency antenna module of claim 6, further comprising a temperature sensor coupled to the microcontroller, and configured to sense a temperature of the radio frequency antenna module.

9. The radio frequency antenna module of claim 8, wherein the lookup table stores phase offsets of the radio frequency antenna corresponding to a plurality of temperatures and a plurality of radio frequencies.

10. The radio frequency antenna module of claim 9, wherein the microcontroller reads the lookup table according to the frequency of the amplified radio frequency signal and the temperature of the radio frequency antenna module to output the phase offset for the radio frequency signal to shift.

11. An antenna array comprising:
a radio frequency signal generator configured to generate a radio frequency signal;
a phase shifter coupled to the radio frequency signal generator, and configured to calibrate the radio frequency signal to generate an input radio frequency signal;
a radio frequency amplifier module coupled to the phase shifter, and comprising:
a radio frequency amplifier configured to amplify the input radio frequency signal to generate an amplified radio frequency signal; and
a memory configured to store a first lookup table that stores phase offsets of the radio frequency amplifier corresponding to a plurality of radio frequencies; and
a radio frequency antenna module coupled to the radio frequency amplifier module, and comprising:
a radio frequency antenna configured to transmit the amplified radio frequency signal.

12. The antenna array of claim 11, further comprising a microcontroller coupled to the radio frequency antenna module, the radio frequency amplifier module and the phase shifter, and configured to read the first lookup table according to at least a frequency of the radio frequency signal to output a phase offset for the radio frequency signal to be shifted to the phase shifter.

13. The antenna array of claim 11, wherein:
the radio frequency antenna module further comprises a memory that stores a second lookup table which stores phase offsets of the radio frequency antenna corresponding to a plurality of radio frequencies; and
the antenna array further comprises a microcontroller coupled to the radio frequency antenna module, the radio frequency amplifier module and the phase shifter, and configured to read the first lookup table and the second lookup table according to at least a frequency of the radio frequency signal to output a phase offset for the radio frequency signal to be shifted to the phase shifter.

14. The antenna array of claim 13, wherein the microcontroller outputs the phase offset for the radio frequency signal to be shifted to the phase shifter according to a radiation angle of the antenna array and the frequency of the radio frequency signal.

15. The antenna array of claim 13, wherein:
the radio frequency amplifier module further comprises a temperature sensor configured to sense a temperature of the radio frequency amplifier module;
the radio frequency antenna module further includes a temperature sensor configured to sense a temperature of the radio frequency antenna module;
the first lookup table stores phase offsets of the radio frequency amplifier corresponding to a plurality of temperatures and a plurality of radio frequencies of the radio frequency amplifier module;
the second lookup table stores phase offsets of the radio frequency antenna corresponding to a plurality of temperatures and a plurality of radio frequencies of the radio frequency antenna module; and
the microcontroller reads the first lookup table and the second lookup table according to at least the temperature of the radio frequency amplifier module, the temperature of the radio frequency antenna module and the frequency of the radio frequency signal to output the phase offset for the radio frequency signal to be shifted to the phase shifter.

16. The antenna array of claim 15, wherein the microcontroller outputs the phase offset of the radio frequency signal to be shifted to the phase shifter according to a radiation angle of the antenna array, the temperature of the radio frequency amplifier module, the temperature of the radio frequency antenna module and the frequency of the radio frequency signal.

17. An antenna array comprising:
a radio frequency signal generator configured to generate a radio frequency signal;
a first phase shifter coupled to the radio frequency signal generator, and configured to calibrate the radio frequency signal to generate an input radio frequency signal;
a radio frequency amplifier module comprising:
a second phase shifter coupled to the first phase shifter, and configured to shift a phase of the input radio frequency signal to generate a phase shifted radio frequency signal;
a radio frequency amplifier coupled to the second phase shifter, and configured to amplify the phase shifted radio frequency signal to output an amplified radio frequency signal;
a first memory configured to store a first lookup table that stores phase offsets of the radio frequency amplifier corresponding to a plurality of radio frequencies; and
a first microcontroller coupled to the second phase shifter and the first memory, and configured to read the first lookup table according to at least a frequency of the input radio frequency signal to output a phase offset for the input radio frequency signal to be shifted to the second phase shifter;
a radio frequency antenna module comprising:
a radio frequency antenna coupled to the radio frequency amplifier, and configured to transmit the amplified radio frequency signal;
a second memory configured to store a second lookup table that stores phase offsets of the radio frequency antenna corresponding to a plurality of radio frequencies; and
a second microcontroller coupled to the second memory, and configured to read the second lookup table according to at least the frequency of the amplified radio frequency signal to output a phase offset of the radio frequency antenna; and
a third microcontroller coupled to the second microcontroller and the first phase shifter, and configured to output to the first phase shifter a phase offset for the radio frequency signal to be shifted according to at least the phase offset of the radio frequency antenna.

18. The antenna array of claim 17, wherein:
the radio frequency amplifier module further comprises a temperature sensor configured to sense a temperature of the radio frequency amplifier module;
the radio frequency antenna module further comprises a temperature sensor configured to sense a temperature of the radio frequency antenna module;
the first lookup table stores phase offsets of the radio frequency amplifier corresponding to a plurality of temperatures and a plurality of radio frequencies of the radio frequency amplifier module;
the second lookup table stores phase offsets of the radio frequency antenna corresponding to a plurality of temperatures and a plurality of radio frequencies of the radio frequency antenna module;
the first microcontroller reads the first lookup table according to the temperature of the radio frequency amplifier module and the frequency of the input radio frequency signal to output the phase offset of the input radio frequency signal to be shifted to the second phase shifter; and
the second microcontroller reads the second lookup table according to the temperature of the radio frequency antenna module and the frequency of the amplified radio frequency signal to output the phase offset of the radio frequency antenna to be shifted.

19. The antenna array of claim 17, wherein the third microcontroller outputs to the first phase shifter the phase offset of the radio frequency signal to be shifted according to a radiation angle of the antenna array and the phase offset data of the radio frequency antenna.
